(19) United States
(12) Patent Application Publication
(10) Pub. No.: US 2019/0302380 A1
(43) Pub. Date: Oct. 3, 2019

(54) OPTICAL MODULE COUPLED WITH PHOTONIC DEVICE AND OPTICAL APPARATUS IMPLEMENTING THE SAME

(71) Applicant: SUMITOMO ELECTRIC INDUSTRIES, LTD., Osaka (JP)

(72) Inventors: Akira FURUYA, Osaka (JP); Koichi KOYAMA, Osaka (JP)

(73) Assignee: SUMITOMO ELECTRIC INDUSTRIES, LTD., Osaka (JP)

(21) Appl. No.: 16/355,156

(22) Filed: Mar. 15, 2019

(30) Foreign Application Priority Data
Mar. 28, 2018 (JP) 2018-062073

(51) Int. Cl. G02B 6/42; G02B 6/122; H01S 5/022; H01L 31/0203; H01S 5/10; H01L 31/02; H01L 33/62

(52) U.S. Cl. CPC G02B 6/4206; G02B 6/122; H01S 5/02208; H01S 5/02248; H01L 33/62; H01L 31/0203; H01S 5/1028; H01L 31/02005; H01S 5/02296

(57) ABSTRACT

An optical module that enables to couple a semiconductor optical device with a photonic device by a preset angle is disclosed. The optical module provides a housing that installs the semiconductor optical device. The housing provides a bottom with a bottom opening, a ceiling facing the bottom, and at least one side wall connecting the ceiling to the bottom. The side wall includes an outer surface extending along a direction normal to the bottom and an inner surface making an acute angle against the outer surface. The semiconductor optical device is mounted on the inner surface facing the one end thereof against the bottom opening to optically couple with an optical signal through the bottom opening.

The present application is based on and claims benefit of priority of Japanese Patent Application No. 2018-062073, filed on March 28,2018, the entire content of which is incorporated herein by reference.

### BACKGROUND OF INVENTION

### 1. Field of Invention

The present invention relates to an optical module, in particular, the invention relates to an optical module optically coupled with a photonic device, and an optical apparatus including the optical module and the photonic device

### 2. Background Arts

A United States Patent, U.S. Pat. No. 8,772,704B, has disclosed an optical assembly for a light source that includes a semiconductor laser diode (LD) and a mirror each mounted on a top surface of a bench device that collectively forms an optical assembly Specifically, the optical assembly disclosed therein, which is placed on a support facing a back surface opposite to the top surface thereof against the top surface of the support, may output an optical beam generated in the LD by reflecting the optical beam by the mirror formed in one edge of the bench device with a substantially right angle because the placement of the sub-optical assembly on the bench device automatically detemiines a direction of the optical beam just output from the LD. However, the reflection by the bench device inevitably causes optical loss. An arrangement for optically coupling an optical module with a photonic dev ice by a designed angle without using reflection has been eagerly requested in the field

### SUMMARY OF INVENTION

An aspect of the present invention relates to an optical module that is to be optically coupled with a photonic device. The optical module includes a semiconductor optical device with a front end and a rear end, and a housing that encloses the semiconductor optical device. The housing provides a frame and a terminal, the frame having a bottom, a bottom opening, a ceiling facing the bottom, and at least one side wall connecting the bottom with the ceiling. The frame is made of a sintering ceramic. The housing has an axis normal to the bottom thereof. The one side wall provides an outer surface extending parallel to the axis and an inner surface making a substantial acute angle against the axis. A feature of the optical module of the present invention is that the semiconductor optical device is mounted on the inner surface of the one side wall facing the front end thereof against the bottom opening to optically couple with an optical signal passing through the bottom opening.

Another aspect of the present invention relates to an optical apparatus that includes a photonic device and an optical module. The photonic device, which processes an optical signal, provides a top surface with a normal thereof. The optical module includes a semiconductor optical device with a front end, and a housing that encloses the semiconductor optical device therein. The housing provides a frame and a terminal, the frame including a bottom, a bottom opening, a ceiling facing the bottom, and at least one side wall connecting the bottom with the ceiling. The frame is made of a sintering ceramic. The one side wall provides an outer surface and an inner surface, where the outer surface extends parallel to the normal of the top surface of the photonic device, while, the inner surface makes a substantial acute angle against the normal of the top surface of the photonic device. A feature of the optical apparatus of the present invention is that the semiconductor optical device is mounted on the inner surface of the one side wall of the housing and faces the front end thereof against the bottom opening to optically couple with the optical signal passing through the bottom opening.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a cross sectional view schematically illustrating an optical apparatus according to an embodiment of the present invention;

FIG. 2 is an exploded view of an optical module implemented within the optical apparatus shown in FIG. 1;

FIG. 3A to FIG. 3F are cross sectional views of a housing, in particular, a first side wall of the housing, which are taken along the line III-III indicated in FIG. 2;

FIG. 4A to FIG. 4H are cross sectional views of the housing, in particular, the first side wall thereof, which are taken along the line IV1-IV1 for FIG. 4A to FIG. 4D, and the line IV2-IV2 for FIG. 4D to FIG. 4E;

FIG. 5A to FIG. 5E show the housing for the optical module according to the embodiment of the present invention;

FIG. 6 is a plan view of an arrangement in the outer surface of the first side wall, which is modified from the arrangement shown in FIG. 5D;

FIG. 7A to FIG. 7D show arrangements of the housing modified from those shown in FIG. 5A to FIG. 5E;

FIG. 8A to FIG. 8D show arrangements of the housing also modified from those shown in FIG. 5A to FIG. 5D;

FIG. 9A and FIG. 9B schematically show a step of assembling the optical module according to the embodiment of the present invention;

FIG. 10A and FIG. 10B schematically show a step of assembling the optical module subsequent to those shown in FIG. 9A and FIG. 9B; and

FIG. 11A and FIG. 11B schematically show a step of assembling the optical module subsequent to those shown in FIG. 11A and FIG. 11B.

### DESCRIPTION OF EMBODIMENTS

Next, some embodiments according to the present invention will be described referring to drawings. In the description of the drawings, numerals or symbols same with or similar to each other will refer to elements same with or similar to each other without duplicating explanations.

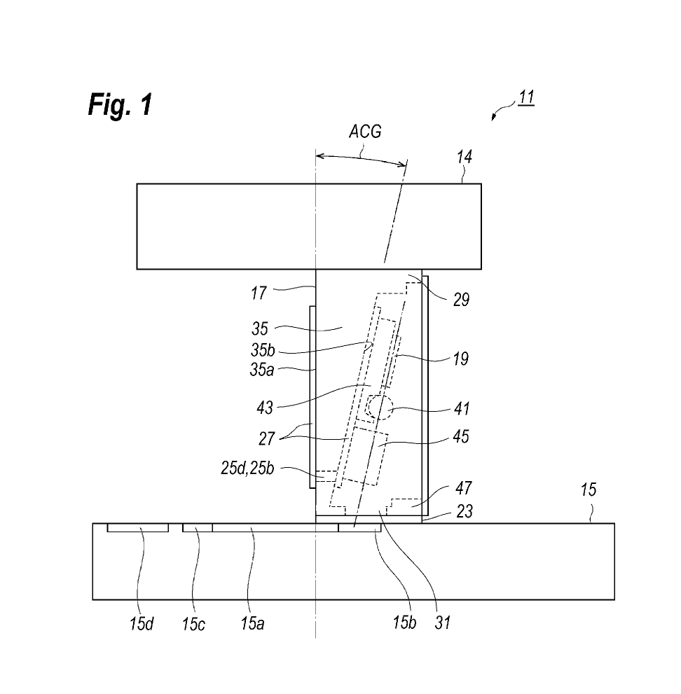

FIG. 1 is a cross sectional view schematically illustrating an optical apparatus according to an embodiment of the present invention, and

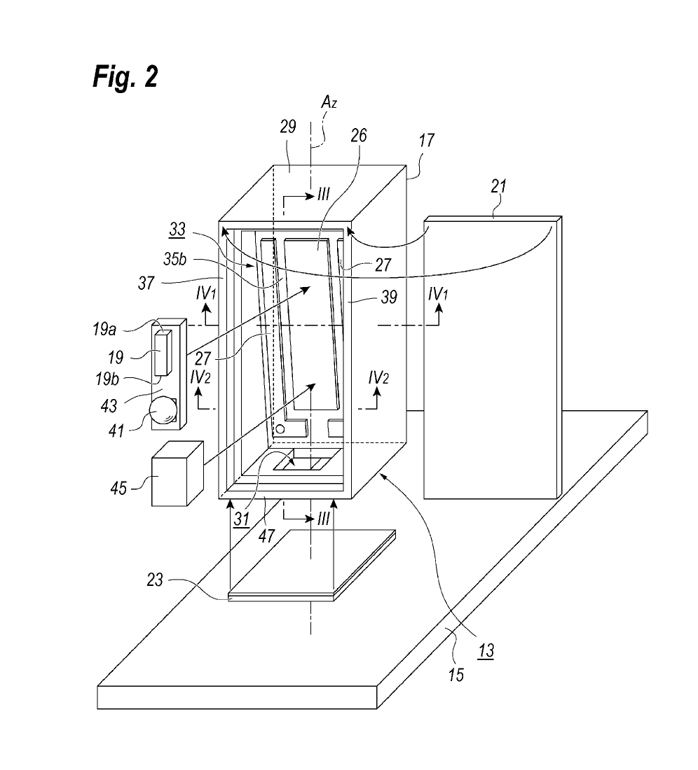

FIG. 2 is an exploded view of the optical apparatus illustrate in FIG. 1.

The optical apparatus 11 of the present embodiment includes an optical module 13 and a photonics device 15 that provides an optical waveguide 15a, an optical coupler 15b such as grating coupler, an optical processing device 15c such as photodiode and/or optical modulator, and an electronic circuit 15d such as an amplifier for amplifying a photocurrent generated by the photodiode and/or a driver for the optical modulator. The optical module 13, which is mounted on the photonics device 15, optically couples with the optical coupler 15b in the photonics device 15 by attaching the photonics device thereto with an adhesive.

The optical module 13 includes a housing 17 and a semiconductor optical device 19. The semiconductor optical device 19 provides a rear end 19a and a front end 19b, while, the housing 17 provides an optical window 23, where the front end 19b of the semiconductor optical device 19 optically couples with the optical window 23. The description below defines directional terms of “front”, “forward”, “rear”, “back”, and so on, but those definitions are merely for explanation sakes, and could not affect the scope of the present invention. The “rear”, “back”, and so on have meanings merely to opposite to “front”, “forward”, and so on. The housing 17 provides a frame 25 and a terminal 27. The frame 25 is made of a sintering ceramic. The terminal 27 is made of a metal. The frame 25 has a ceiling 29, a bottom opening 31, a side opening 33, a bottom 47, and first to third side walls, 35, 37, and 39. As shown in FIG. 2, the ceiling 29 faces the bottom 47, the first side wall 35 faces the side opening 33, and the second side wall 37 faces the third side wall 39. Accordingly, the ceiling 29, the second side wall 37, the third side wall 39, and the bottom 47 demarcates the side opening 33 by extending from respective edges of the first side wall 35. The frame 25 of the housing 17 may further provide via holes, 25a and 25b, in the first side wall 35, from which terminals 27 extend.

The housing 17 provides a side cover 21 that caps the side opening 33, while, the optical window 23 covers the bottom opening 31. The window 23 includes an outer surface and an inner surface, at least one of which provides an anti-reflection film. The frame 25, the terminal 27, the side cover 21, and the optical window 23 air-tightly seal a cavity, within which the semiconductor optical device 19 is enclosed so as to align an optical axis thereof along an axis A_{z} connecting the optical window 23 with the ceiling 29. Specifically, the semiconductor optical device 19 is mounted on an inner surface 35b of the first side wall 35.

The first side wall 35 provides an outer surface 35a and the inner surface 35b, where the outer surface 35a vertically extends, exactly along the axis A_{z}, namely, a normal of a top surface of the photonic device 15 when the optical module 13 is mounted thereon, while, the inner surface 35b makes a substantial acute angle ACG against the normal of the photonic device 15. Thus, the optical module 13 of the embodiment arranges the semiconductor optical device 19 between the optical window 23 and the ceiling 29. The inner surface 35b makes the substantial angle ACG against the outer surface 35a, that is, the first side wall 35 has a graded thickness gradually and linearly thinning from the ceiling 29 to the bottom 47.

Table below lists details of elements in the optical apparatus 11:

| | |
|---|---|
| photonic device 15 | silicon |
| optical module 13 | |
| side cover 21: | plate made of metal, resin, and/or glass |
| window 23: | glass and/or resin |
| frame 25: | aluminum nitride, silicon carbide, or alumina |
| terminal 27: | gold (Au), nickel (Ni), copper (Cu), and/or |
| | tungsten (W) |
| angle AGC: | 12 to 19° |

The semiconductor optical device 19 is mounted on the inner surface 35b directly or indirectly using a sub-mount 43. An optical beam subject to the semiconductor optical device 19, namely, an incoming beam or an outgoing beam, advances parallel to the inner surface 35b. The optical module 13 may further implement a lens 41 to couple the semiconductor optical device 19 with the photonic device 15 through the optical window 23. The semiconductor optical device 19 of the present embodiment may be a light-emitting device or a light-receiving device, where the former device is typically a semiconductor laser diode (LD) and/or a semiconductor light emitting diode (LED), while, the latter device is typically a semiconductor photodiode (PD). The optical module 13 may further provide the sub-mount 43 to mount the lens 41 and the semiconductor optical device 19 thereon. The optical beam, specifically, the outgoing beam advances in parallel to the inner surface 35b from the semiconductor optical device 19 to the optical window 23 within the housing 17, and externally output through the optical window 23. The outgoing beam enters the optical coupler 15b provided in the photonics device 15 through the optical window 23.

The optical module 13 may further provide an optical isolator 45 between the optical window 23 and the semiconductor optical device 19. Also, the incoming beam directing to the semiconductor optical device 19 passes the optical window 23 and advances in parallel to the inner surface 35b making the angle ACG against the normal of the photonic device 15. The incoming beam coming from the optical coupler 15b in the photonic device 15 is tilted with respect to the normal of the photonic device 15. The angle AGC of the inner surface 35b makes it possible to couple the incoming beam with the semiconductor optical device 19 through the optical window 23.

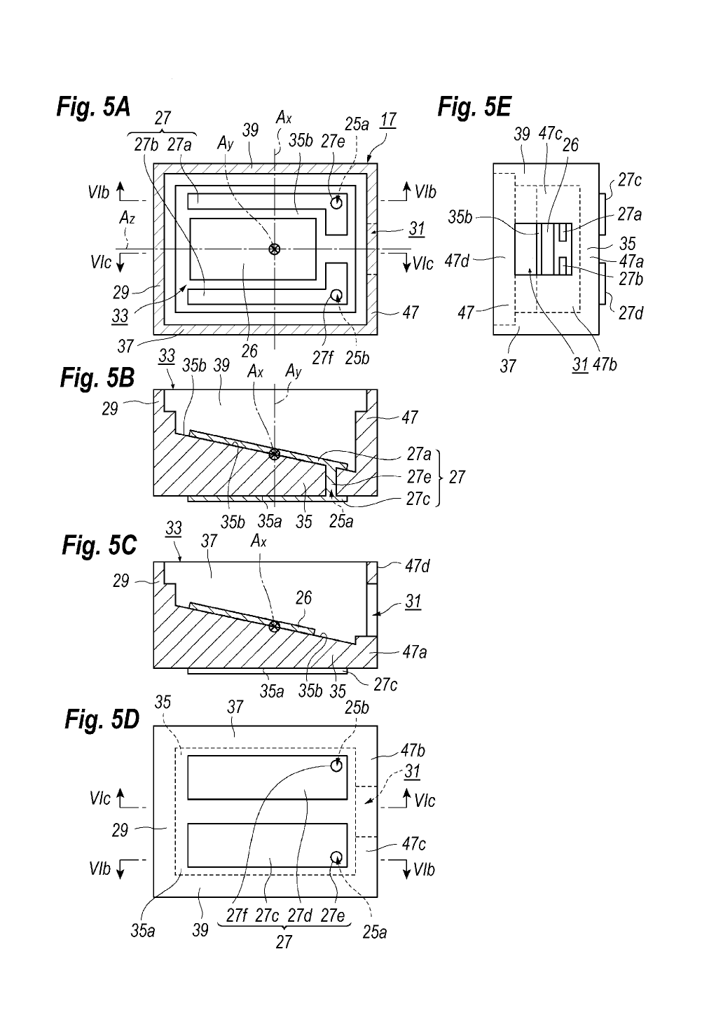

The first side wall 35 may further provides via holes, 25a and 25b, through which the terminals 27 extend. Thus, according to the embodiment, the first side wall 35 may provide a structure for electrically coupling the semiconductor optical device 19 with external devices. Specifically, the first side wall 35 provides the via holes, 25a and 25b, piercing from the outer surface 35a to the inner surface 35b. The terminals 27 provide first and second inner metal layers, 27a and 27b, on the inner surface 35b, first and second outer metal layers, 27c and 27d, on the outer surface 35a, and first and second metal plugs, 27e and 27f, filling the via holes, 25a and 25b, where the metal layers, 27a to 27d, and the metal plugs, 27e and 27f, are illustrated in FIG. 5 to FIG. 8.

The frame 25 of the housing 17, which includes the ceiling 29, the first to third side walls 35 to 39, and the bottom 47, may be monolithically and unitedly formed from a single piece of sintering ceramics. Referring to FIG. 1 again, the optical apparatus 11 may further include, in addition to the optical module 13 and the photonic device 15, a heat spreader 14 attached to the ceiling 29 of the housing 17 to radiate heat generating by the semiconductor optical device 19 in the housing 17 and being conducted in the first side wall 35 to the ceiling 29.

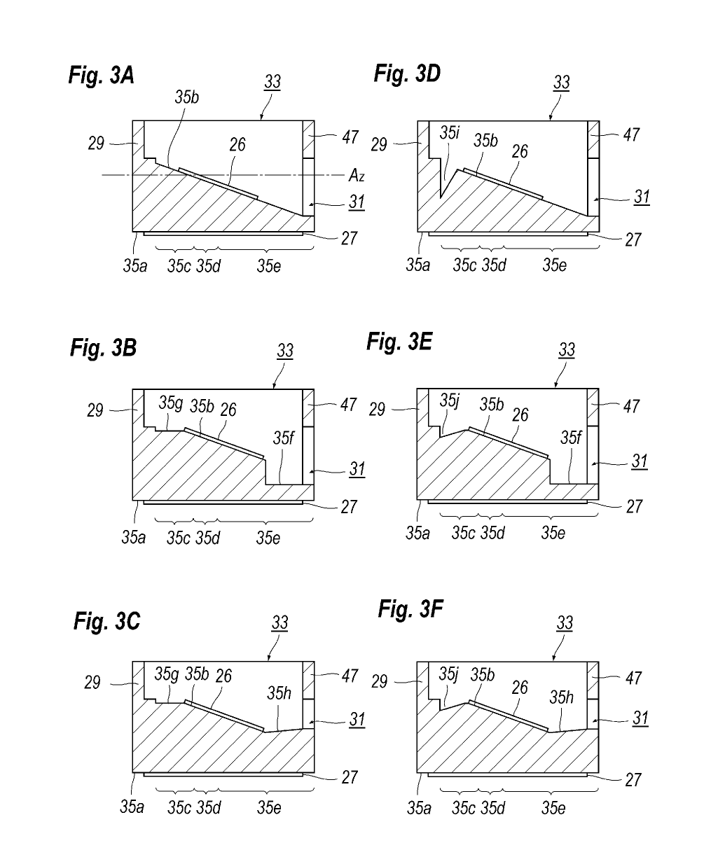

Next, various modifications of the housing 17, in particular, the first side wall 35 thereof, will be described. FIG. 3A is a cross sectional view of the first side wall 35 that is taken along the line III-III indicated in FIG. 2, and FIG. 3B to FIG. 3F are also cross sectional views of modified first side walls 35 that are also taken along the line III-III. The first side wall 35 includes a rear portion 35c, a center portion 35d, and a front portion 35e arranged in this order along the axis A_{z} from the ceiling 29 to the bottom 47. When the semiconductor optical device 19 is a light-emitting device, typically semiconductor laser diode (LD), semiconductor light-emitting diode (LED), and so on, such a light-emitting device is mounted in the center portion 35d to emit an optical beam to the photonic device 15 with the angle ACP determined by the first side wall 35.

Specifically, the first side wall 35 has a thickness monotonically increasing from a side of the bottom 47 to another side of the ceiling 29, which may effectively secure a heat-dissipating path for the semiconductor optical device 19 mounted on the center portion 35d. When the semiconductor optical device is a type of light-receiving device typically semiconductor photodiode (PD), such a light-receiving device may be mounted also on the center portion 35d to receive an optical beam coming from the photonic device 15 with the angle of ACP determined by the slope of the inner surface 35b.

The inner surface 35b of the first side wall 35, which extends from an inner surface of the ceiling 29 to an inner surface of the bottom 47 smoothly without forming any specific structures; while, the semiconductor optical device 19 provides the rear end 19a and the front end 19b. Accordingly, the respective portions, 35c to 35e, may be determined by an area from the inner surface of the ceiling 29 to the rear end 19a of the semiconductor optical device 19, an area between the rear end 19a to the front end 19b of the semiconductor optical device 19, and an area from the front end 19b of the semiconductor optical device 19 to the inner surface of the bottom 47.

Referring to FIG. 3A, which corresponds to the arrangement shown in FIG. 2, the front portion 35e has a maximum thickness at an interface against the center portion 35d; the rear portion 35c has a minimum thickness at an interface against the center portion 35d; and the center portion 35d has a thickness that is greater than the maximum thickness of the front portion 35e but smaller than the minimum thickness of the rear portion 35c in whole portions thereof. The rear portion 35c has a thickness preferably greater than the maximum thickness of the front portion 35e in whole portions thereof, which means that the rear portion 35c has a minimum thickness that is greater than the maximum thickness of the front portion 35e.

FIG. 3B illustrates a cross section of the modified first side wall 35, where the front portion 35e has a hollow 35f in a portion closer to the bottom 47 but has the maximum thickness at the interface against the center portion 35d; while, the rear portion has a plateau 35g in a portion closer to the ceiling 29 but has the minimum thickness at the interface against the center portion 35d. That is, the semiconductor optical device 19 is mounted on the slope in the center portion 35d but free from the plateau 35g and the hollow 35f. The hollow 35f formed in the portion closer to the bottom 47 may expose the bottom opening 31 wide enough, which secures an arrangement not to restrict the field diameter of the optical beam subject to the semiconductor optical device 19.

FIG. 3C is a cross sectional view of the first side wall 35 according to another modification, where the front portion 35e provides a reverse slope 35h in a portion closer to the bottom 47, that is, the front portion 35e in a thickness thereof becomes a minimum at a root of the reverse slope 35h and gradually increases toward the bottom 47 but becomes the maximum at the interface against the center portion 35d.

FIG. 3D is also a cross sectional view of a modified first side wall 35, where the front portion 35e has the arrangement same with that shown in FIG. 3A, but the rear portion 35c provides a deep groove 35i at the interface against the ceiling 29. The center portion 35d is free from the groove 35i, that is, the groove 35i exists only in the rear portion 35c so as to intersect the axis A_{z}, and the semiconductor optical device 19 is not influenced from the existence of the groove 35i.

Referring to FIG. 3E, which is also a cross sectional view of a modified first side wall 35, the front portion 35e has the arrangement same with that shown in FIG. 3B but the rear portion 35c provides a shallow groove 35j in an area closer to the ceiling 29.

Referring to FIG. 3F, which is also a cross sectional view of a modified first side wall 35, the front portion 35e has the arrangement same with that shown in FIG. 3C, while, the rear portion 35c also has the arrangement same with that shown in FIG. 3E.

Thus, as various modifications illustrate from FIG. 3B to FIG. 3F, the center portion 35d, where the semiconductor optical device 19 is mounted thereon, may be free from structures in the rear portion 35c and the front portion 35e, that is, the center portion 35d provides a smooth slope from the interface against the rear portion 35c to the interface against the front portion 35e. Accordingly, the arrangements of the first side wall 35 may provide the effective heat-dissipating path from the semiconductor optical device 19 in the center portion 35d to the ceiling 29.

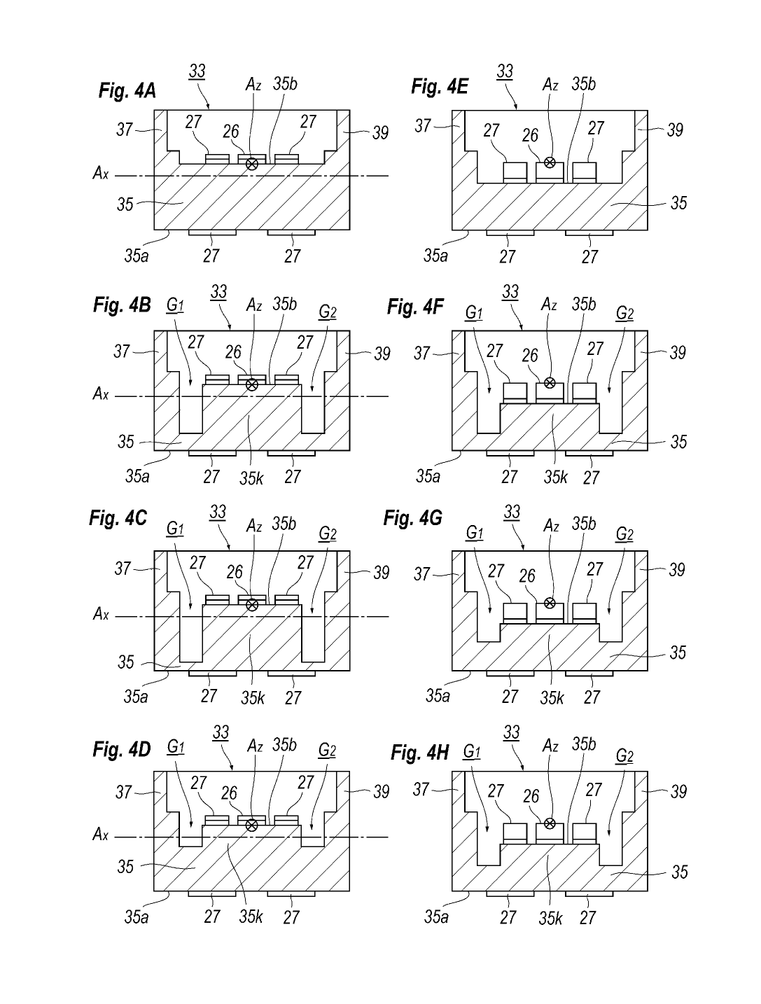

FIG. 4A to FIG. 4D illustrate cross sectional views of the first side wall 35 that are taken along the line IV1-1V1 indicated in FIG. 2, while, FIG. 4E to FIG. 4H are cross sectional views of the first side wall 35 taken along the line IV2-IV2 also indicated in FIG. 2, where the line IV2-IV2 is set relatively closer to the bottom 47. The arrangements shown in FIG. 4A to FIG. 4H concentrate for the first side wall 35 shown in FIG. 3A; but the explanations are similarly applicable to the modified side walls shown in FIG. 3B to FIG. 3F.

Referring to FIG. 4A and FIG. 4E, the inner surface 35b fully extends from the second side wall 37 to the third side wall 39 along the axis Aₓ without forming any grooves against the second and third side walls, 37 and 39. Referring to FIG. 4B and FIG. 4F, the inner surface 35b provides a terrace 35k provided between two grooves, G₁ and G₂. That is, the terrace 35k is divided from the second side wall 37 by the groove G₁ and from the third side wall 39 by the other groove G₂, where the side wall 35 has thicknesses between the outer surface 35a and the bottoms of the grooves, G₁ and G₂, that is constant along the direction A_{z}, namely, from the side of the ceiling 29, which is shown in FIG. 4B, to the other side of the bottom 47, which is shown in FIG. 4F. The semiconductor optical device 19 is mounted on the terrace 35k.

Referring to FIG. 4C and FIG. 4Q the first side wall 35 also provides the grooves, G₁ and G₂, that divide the terrace 35k from the side walls, 37 and 39. A feature of the arrangement shown in FIG. 4C and FIG. 4Q is that the grooves, G₁ and G₂, has a depth gradually shallowing from the side of the ceiling 29 to the other side of the bottom 47. That is, the first side wall 35 has the thickness between the bottoms of the grooves, G₁ and G₂, and the outer surface 35a that are gradually thicker from the side of the ceiling 29, which shown in FIG. 4C, to the other side of the bottom 47, which is shown in FIG. 4G.

Referring to FIG. 4D and FIG. 4H, the first side wall 35 also provides the terrace 35k that is divided from the side walls, 37 and 39, by two grooves, G₁ and G₂. A feature of the arrangement shown in FIG. 4D and FIG. 4H is that the terrace 35k has a height measured from the bottom of the grooves, G₁ and G₂, constant from the side of the ceiling 29 to the other side of the bottom 47. That is, the first side wall 35 has thicknesses between the outer surface 35a thereof and the bottom of the grooves, G₁ and G₂, that is gradually thinner from the side of the ceiling 29, which is shown in FIG. 4D, to the other side of the bottom 47, which is shown in FIG. 4H.

Thus, even when the terrace 35k is divided from the side walls, 37 and 39, by the grooves, G₁ and G₂, as shown in FIG. 4B to FIG. 4D and FIG. 4F to FIG. 4H, the first side wall 35 may smoothly continue from ceiling 29 to the bottom 47, which may secure the effective heat-dissipating path from the semiconductor optical device 19 mounted on the terrace to the outside of the optical module 13.

FIG. 5A to FIG. 5E show the arrangement of the housing 17, in particular, the first side wall 35 thereof, where FIG. 5A is a plan view of the inner surface 35b, FIG. 5B and FIG. 5C are cross sectional views, FIG. 5D is a plan view of the outer surface 35a, of the first side wall 35, and FIG. 5E is a front view of the housing 17.

The bottom 47 of the housing 17 provides the bottom opening 31 that is covered with the optical window 23, through which the inner surface 35b of the first side wall 35 may be inspected as shown in FIG. 5E. Further specifically, the bottom 47 provides four frames, 47a to 47d, that demarcate and support the bottom window 23 therein, where the first frame 47a extends along the axis Aₓ and the first side wall 35 builds therefrom along the axis A_{z}; the second frame 47b and the third frame 47c extend along the axis A_{y}, where the second and third side walls, 37 and 39, build therefrom along the axis A_{z}; and the fourth frame 47d extend along the axis Aₓ and connects the second frame 47b with the third frame 47c.

The side opening 33 may be defined by the ceiling 29, the second and third side walls, 37 and 39, and the bottom 47, specifically, the fourth frame 47d of the bottom 47. The side cover 21 is fixed to respective edges of the ceiling 29, the second and third side walls, 37 and 39, and the fourth frame 47d of the bottom 47.

Referring to FIG. 5A to FIG. 5D, the housing 17 provides the terminals 27 that includes first and second inner metal layers, 27a and 27b, first and second outer metal layers, 27c and 27d, and first and second metal plugs, 27e and 27f Moreover, the housing 17 provides a pad 26 in addition to the terminals 27, where the first and second inner metal layers, 27a and 27b, and the pad 26 are formed on the inner surface 35b of the first side wall 35, while, the first and second outer metal layers, 27c and 27d, are provided on the outer surface 35a of the first side wall 35. The first and second metal plugs, 27e and 27f, fill the via holes, 25a and 25b, where the first metal plug 27e electrically connects the first inner metal layer 27a with the first outer metal layer 27c, while, the second metal plug 27f connects the second inner metal layer 27h with the second outer metal layer 27d.

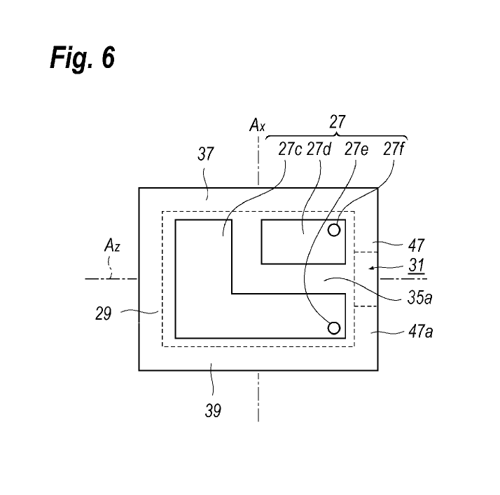

FIG. 6 is a plan view of the outer surface 35a of the first side wall 35. The first and second outer metal layers, 27c and 27d, in the arrangements thereof are not restricted to those shown in FIG. 5D, and may have another arrangement shown in FIG. 6.

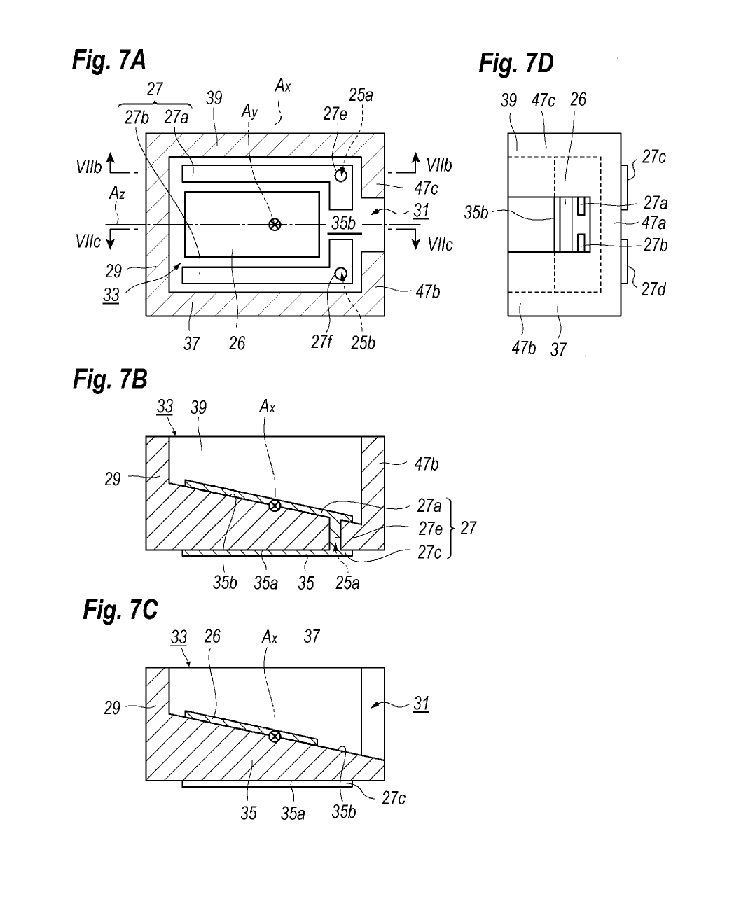

FIG. 7A to FIG. 7D show arrangements of another housing 17 modified from that shown in FIG. 5A to FIG. 5D, where FIG. 7A is a plan view of the inner surface 35b, FIG. 7B and FIG. 7C are cross sectional views of the housing 17 each taken along the line VIIb-VIIb and the line VIIc-VIIIc indicated in FIG. 7A, and FIG. 7D is a bottom view of the housing 17. Referring to FIG. 7D, the housing 17 provides the bottom 47 including the bottom opening 31 formed by the three frames, 47a to 47c, without providing the fourth frame 47d. That is, the housing 17 shown in FIG. 7A to FIG. 7D has a feature that the fourth frame 47d in the bottom 47 is omitted such that the bottom opening 31 continues to the side opening 33. Other arrangements of the housing 17, the terminals 27 including the inner and outer metal layers, 27a to 27d, the metal plugs, 27e and 27f, and the via holes, 25a and 25b, are substantially same with those of the aforementioned embodiment.

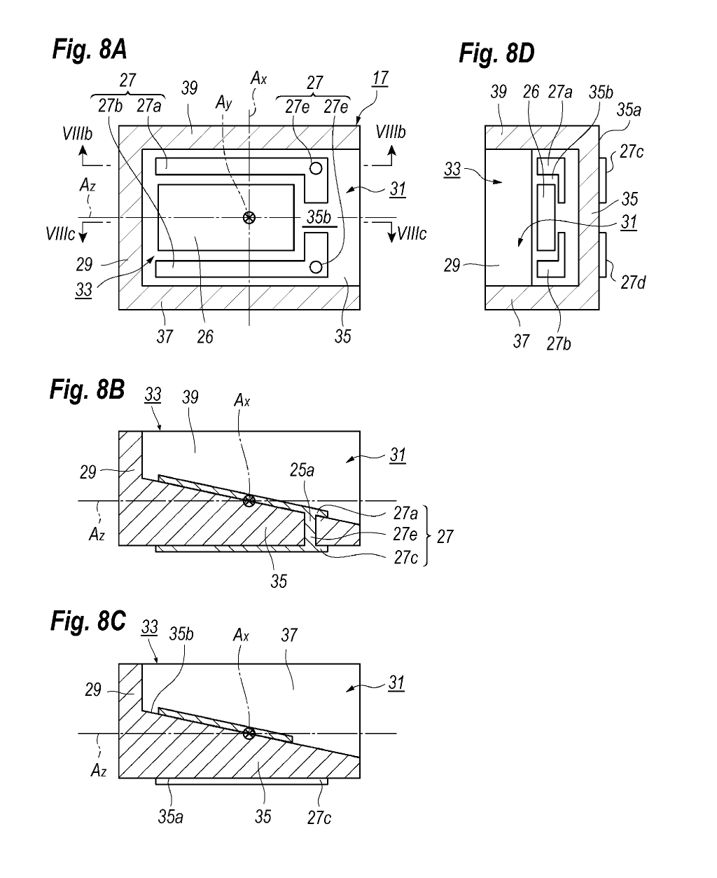

FIG. 8A to FIG. 8D show the housing 17 still modified from that shown in FIG. 5A to FIG. 5D, where FIG. 8A is a plan view of the inner surface 35b, FIG. 8B and FIG. 8C are cross sectional views of the first side wall 35, and FIG. 8D is a bottom view of the housing 17. The housing 17 shown in FIG. 8A to FIG. 8D has a feature that the bottom 47 is fully omitted such that the bottom opening 31 is formed by the edges of the first to third side walls, 35 to 37, and smoothly continues to the side opening 33. Other arrangements of the housing 17 are substantially same with those shown in FIG. 5A to FIG. 5D including the inner and outer metals, 27a to 27d, the plugs, 27e and 27f, and via holes, 25a and 25b, are same with those of the aforementioned embodiments.

A table below summarizes dimensions of the housing 17 according to the present embodiment:

| | | |
|---|---|---|
| span between outer surfaces of second and third side | 2.6 ± 0.05 | mm |
| walls | | |
| span between inner surfaces of second and third side | 2.0 ± 0.05 | mm |
| walls | | |
| width of ceiling, and second and third side walls | 0.3 ± 0.05 | mm |
| span between inner surfaces of ceiling and bottom | 3.1 ± 0.05 | mm |
| span between outer surfaces of ceiling and bottom | 3.4 ± 0.05 | mm |
| diameter of via holes | 0.16 ± 0.03 | mm |
| size of side opening | 3.1 × 2.0 | mm² |

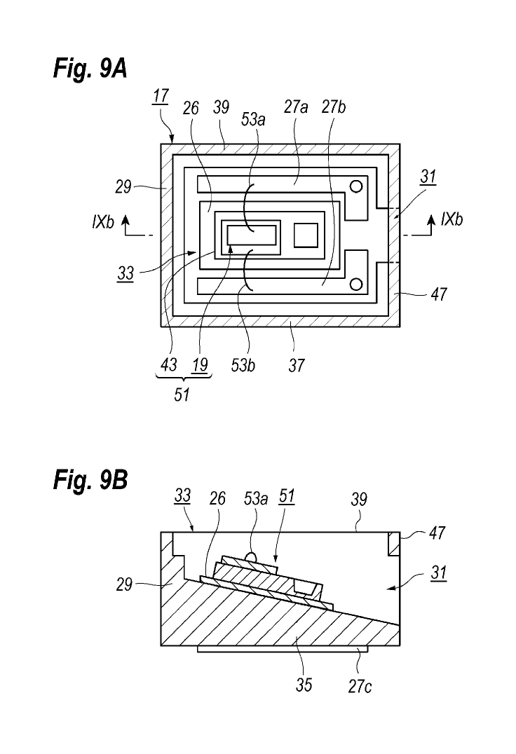

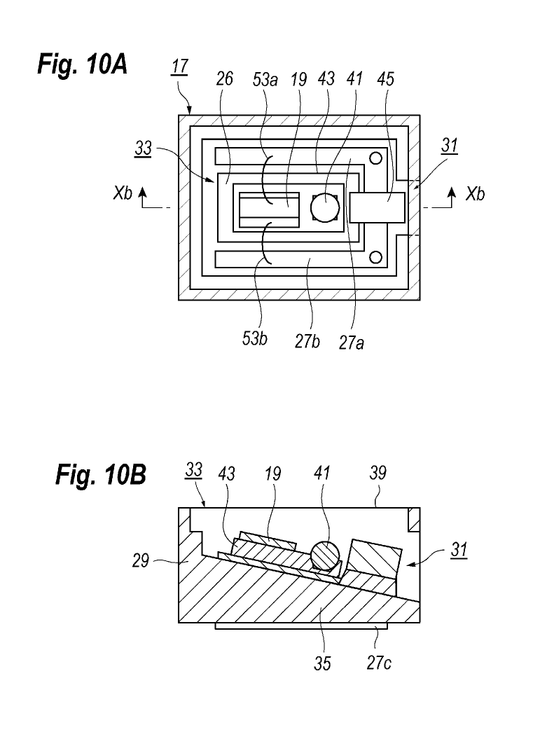

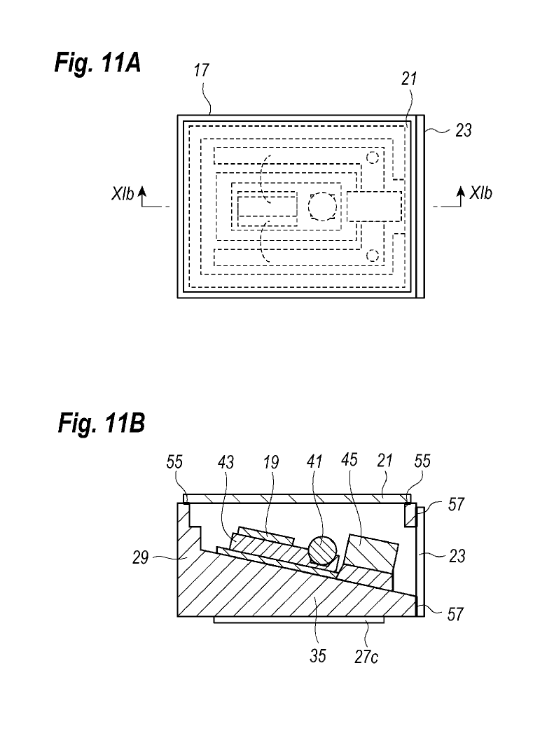

FIG. 9A to FIG. 11B show steps of assembling the optical module 13 according to the present invention, where FIG. 9A, FIG. 10A, and FIG. 11A are plan views of the inner surface 35b and FIG. 9B, FIG. 10B, and FIG. 11B are cross sectional views of the first side wall 35 taken along the lines, IXb-IXb, Xb-Xb and XIb-XIB each indicated in FIG. 9A, FIG. 10A, and FIG. 11A.

As shown in FIG. 9A and FIG. 9B, the process first prepares the housing 17, the semiconductor optical device 13, and the sub-mount 43, then forms a sub-assembly 51 by mounting the semiconductor optical device 19 on the sub-mount 43. Installing the sub-assembly 51 within the housing 17 from the side opening 33, the sub-assembly 51 is mounted on the pad 26. Thereafter, the process carries out the wire-bonding from the semiconductor optical device 19 on the sub-assembly 51 to the inner metal layers, 27a and 27b, on the inner surface 35b with bonding wires, 53a and 53b.

Thereafter, as shown in FIG. 10A and FIG. 10B, the lens 41 and the optical isolator 45 are installed through the side opening 33 and placed on respective positions between the semiconductor optical device 19 and the bottom opening 31. The optical isolator 45 is automatically aligned with the semiconductor optical device 19.

Thereafter, as shown in FIG. 11A and FIG. 11B, the cavity in the housing 17 formed by the first to third side walls, 35 to 37, the ceiling 29, and the bottom 47 with the optical window 23 covering the bottom window 31 is enclosed by attaching the side cover 21 to respective ends of the first to third side walls, 35 to 39, that of the ceiling 29, and that of the bottom 47 with an adhesive.

While particular embodiments and some modifications thereof according to the present invention have been described herein for purposes of illustration, further modifications and changes will become apparent to those skilled in the art. Accordingly, claims attached hereto are intended to encompass all such modifications and changes falling within the true spirit and scope of this invention.

What is claimed is:

1. An optical module optically coupled with a photonic device, comprising:
a semiconductor optical device having a front end; and
a housing that encloses the semiconductor optical device therein, the housing, having a bottom with a bottom opening, a ceiling facing the bottom, and at least one side wall connecting the bottom with the ceiling, the housing having an axis normal to the bottom, the one side wall having an outer surface extending in parallel to the axis and an inner surface making a substantial acute angle against the axis;
wherein the semiconductor optical device is mounted on the inner surface of the one side wall of the housing facing the front end thereof against the bottom opening to optically couple with an optical signal passing through the bottom opening.

2. The optical module according to claim 1,
wherein the one side wall of the housing provides a terminal including an inner metal layer in the inner surface of the one side wall, a via hole piercing the one side wall from the inner surface to the outer surface, and an outer metal layer providing in the outer surface of the one side wall, the via hole being filled with a metal plug,
wherein the inner metal layer, the metal plug, and the outer metal layer are electrically connected each other, and
wherein the terminal is electrically connected with the semiconductor optical device with a bonding wire.

3. The optical module according to claim 1,
wherein the one side wall has a rear portion, a center portion, and a front portion, and
wherein the center portion mounts the semiconductor optical device thereon and has a thickness linearly decreasing from a side of the ceiling to another side of the bottom of the housing.

4. The optical module according to claim 3,
wherein the semiconductor optical device further provides a rear end opposite to the front end thereof, the center portion of the one side wall being demarcated in an area from the rear end to the front end of the semiconductor optical device.

5. The optical module according to claim 4,
wherein the rear portion is demarcated from the rear end of the semiconductor optical device to the ceiling, the rear portion having a plateau with a constant thickness against the outer surface of the one side wall.

6. The optical module according to claim 4,
wherein the front portion of the one side wall is demarcated in an area from the front end of the semiconductor optical device to the bottom of the housing, the front portion having a hollow that exposes the bottom window and has a constant thickness against the outer surface of the one side wall, the constant thickness being smaller than a thickness of the one side wall at an interface between the center portion and the front portion.

7. The optical module according to claim 4,
wherein the rear portion provides a groove traversing the axis.

8. The optical module according to claim 1,
wherein the inner surface of the one side wall provides a pair of grooves each extending along the axis and forming a terrace therebetween where the semiconductor optical device is mounted thereon.

9. The optical module according to claim 1,
wherein the ceiling, the side wall, and the bottom are made of a sintering ceramic.

10. An optical apparatus, comprising:
a photonic device that process an optical signal, the photonic device having a top surface with a normal; and
an optical module including,
a semiconductor optical device having a front end, and
a housing that encloses the semiconductor optical device therein, the housing having a bottom including a bottom opening, a ceiling facing the bottom, and at least one side wall connecting the bottom with the ceiling, the one side wall having an outer surface and an inner surface, the outer surface extending in parallel to the normal of the top surface of the photonic device, the inner surface making a substantial acute angle against the normal of the top surface of the photonic device;
wherein the semiconductor optical device is mounted on the inner surface of the one side wall of the housing and faces the front end thereof against the bottom opening to optically couple with the optical signal through the bottom opening.

11. The optical apparatus according to claim 10,
further including a heat spreader attached to the ceiling of the optical module.

12. The optical apparatus according to claim 10,
wherein the one side wall of the housing provides a terminal including an inner metal layer in the inner surface of the one side wall, a via hole piercing the one side wall from the inner surface to the outer surface, and an outer metal layer providing in the outer surface of the one side wall, the via hole being filled with an metal plug,
wherein the inner metal layer, the metal plug, and the outer metal layer are electrically connected each other, and
wherein the terminal is electrically connected with the semiconductor optical device with a bonding wire.

13. The optical apparatus according to claim 10,
wherein the one side wall has a rear portion, a center portion, and a front portion, the center portion mounting the semiconductor optical device thereon, and
wherein the center portion has a thickness linearly decreasing from a side of the ceiling to another side of the bottom of the housing.

14. The optical apparatus according to claim 13,
wherein the semiconductor optical device further provides a rear end opposite to the front end thereof, the center portion of the one side wall being demarcated in an area from the rear end to the front end of the semiconductor optical device.

15. The optical apparatus according to claim 14,
wherein the rear portion is demarcated in an area from the rear end of the semiconductor optical device to the ceiling, the rear portion having a plateau with a constant thickness against the outer surface of the one side wall.

16. The optical apparatus according to claim 14,
wherein the front portion of the one side wall is demarcated in an area from the front end of the semiconductor optical device to the bottom of the housing, the front portion having a hollow that exposes the bottom window and has a constant thickness against the outer surface of the one side wall, the constant thickness being smaller than a thickness of the one side wall at an interface between the center portion and the front portion.

17. The optical apparatus according to claim 14,
wherein the rear portion provides a groove traversing the normal.

18. The optical apparatus according to claim 10,
wherein the inner surface of the one side wall provides a pair of grooves each extending along the normal of the top surface of the photonic device and forming a terrace therebetween where the semiconductor optical device is mounted thereon.

19. The optical apparatus according to claim 10,
wherein the ceiling, the side wall, and the bottom are made of a sintering ceramic.
